(19) United States
(12) Patent Application Publication
(10) Pub. No.: US 2026/0223555 A1
(43) Pub. Date: Jul. 30, 2026

(54) DISPLAY SUBSTRATE AND MANUFACTURING METHOD THEREFOR, AND DISPLAY DEVICE

(71) Applicants: Hefei Xinsheng Optoelectronics Technology Co., Ltd., Hefei, Anhui (CN); BOE Technology Group Co., Ltd., Beijing (CN)

(72) Inventors: Haitao WANG, Beijing (CN); Ming WANG, Beijing (CN); Shi SUN, Beijing (CN); Yongchao HUANG, Beijing (CN); Jun CHENG, Beijing (CN)

(21) Appl. No.: 19/146,555

(22) PCT Filed: Jul. 17, 2024
(86) PCT No.: PCT/CN2024/105947

§ 371 Date: Jul. 9, 2025

(30) Foreign Application Priority Data
Aug. 28, 2023 (CN) 202311092105.X

(51) Int. Cl. H10K 59/131; H10K 59/12

(52) U.S. Cl. CPC H10K 59/131; H10K 59/1201

(57) ABSTRACT

A display substrate and a manufacturing method therefor, and a display device. The display substrate includes a display area and a frame area, and a storage capacitor includes a first electrode plate, a second electrode plate and a third electrode plate. The display substrate includes a first conductive layer, a second conductive layer and a third conductive layer, wherein the first electrode plate is arranged in the first conductive layer, a first signal line and the second electrode plate are arranged in the second conductive layer, and a second signal line and the third electrode plate are arranged in the third conductive layer. Two of the first electrode plate, the second electrode plate and the third electrode plate are provided with notches.

### CROSS-REFERENCE TO RELATED APPLICATION

The present application is a U.S. National Phase Entry of International Application No. PCT/CN2024/105947 having an international filing date of Jul. 17, 2024, which claims priority to Chinese Patent Application No. 202311092105.X, filed to the CNIPA on Aug. 28, 2023 and entitled “Display Substrate and Manufacturing Method Therefor, and Display Device”. Contents of the above-identified applications are incorporated into the present application by reference.

### TECHNICAL FIELD

The present disclosure relates to, but is not limited to, a field of display apparatus technology, and particularly to a display substrate and a manufacturing method therefor, and a display device.

### BACKGROUND

An organic light-emitting diode (OLED) and a quantum dot light-emitting diode (QLED) are active light-emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display device (Flexible Display) in which an OLED or a QLED is used as a light-emitting device and signal control is performed through a thin film transistor (TFT) has become a mainstream product in the field of display at present.

At present, the success rate of capacitor maintenance is low in the process of preparation of large-size transparent products.

### SUMMARY

The following is a summary of subject matters described herein in detail. This summary is not intended to limit the protection scope of claims.

At least one embodiment of the present disclosure provides a display substrate including a display area and a bezel area located on at least one side of the display area, the bezel area including at least a gate driving circuit. The gate driving circuit includes at least a storage capacitor, a first signal line, and a second signal line, the storage capacitor including a first electrode plate, a second electrode plate, and a third electrode plate that are stacked. In a direction perpendicular to the display substrate, the display substrate includes a first conductive layer, a second conductive layer, and a third conductive layer sequentially disposed on a base substrate along a direction away from the base substrate.

The first electrode plate is disposed in the first conductive layer. The first signal line and the second electrode plate are disposed in the second conductive layer, the second electrode plate having a first input terminal connected to the first signal line. The second signal line and the third electrode plate are disposed in the third conductive layer, the third electrode plate having a second input terminal connected to the second signal line. Two of the first electrode plate, the second electrode plate, and the third electrode plate are provided with notches, and orthographic projections of the notches on the base substrate are configured to overlap with an orthographic projection of the first input terminal on the base substrate, or an orthographic projection of the second input terminal on the base substrate.

In some exemplary embodiments, both the first electrode plate and the third electrode plate are provided with the notches, and the orthographic projections of the notches on the base substrate overlap with the orthographic projection of the first input terminal on the base substrate. Alternatively, both the first electrode plate and the second electrode plate are provided with the notches, and the orthographic projections of the notches on the base substrate overlap with the orthographic projection of the second input terminal on the base substrate.

In some exemplary embodiments, a circumferential edge of the first electrode plate is provided with a first groove recessed inward, the first groove extending in a direction perpendicular to the base substrate and penetrating the first electrode plate. A circumferential edge of the third electrode plate is provided with a second groove recessed inward, the second groove extending in the direction perpendicular to the base substrate and penetrating the third electrode plate. Both the first groove and the second groove constitute the notches.

In some exemplary embodiments, the circumferential edge of the first electrode plate includes at least a first edge, the first edge being located on a side of the first electrode plate close to the first input terminal, the first groove being provided on the first edge. The circumferential edge of the third electrode plate includes at least a second edge, the second edge being located on a side of the third electrode plate close to the first input terminal, the second groove being provided on the second edge. The first edge and the second edge are flush in the direction perpendicular to the base substrate, and an orthographic projection of the first groove on the base substrate and an orthographic projection of the second groove on the base substrate at least partially overlap.

In some exemplary embodiments, the orthographic projection of the first groove on the base substrate is within a range of the orthographic projection of the second groove on the base substrate. Alternatively, the orthographic projection of the second groove on the base substrate is within a range of the orthographic projection of the first groove on the base substrate. Alternatively, the orthographic projection of the first groove on the base substrate and the orthographic projection of the second groove on the base substrate overlap.

In some exemplary embodiments, both a shape of the first groove and a shape of the second groove are rectangular or arc-shaped in a direction parallel to the base substrate.

In some exemplary embodiments, a groove width of the first groove and a groove width of the second groove are both 15 μm to 30 μm, and a groove depth of the first groove and a groove depth of the second groove are both 7 μm to 15 μm.

In some exemplary embodiments, a circumferential edge of the first electrode plate is provided with a third groove recessed inward, the third groove extending in a direction perpendicular to the base substrate and penetrating the first electrode plate. A circumferential edge of the second electrode plate is provided with a fourth groove recessed inward, the fourth groove extending in the direction perpendicular to the base substrate and penetrating the second electrode plate. Both the third groove and the fourth groove constitute the notches, and an orthographic projection of the third groove on the base substrate and an orthographic projection of the fourth groove on the base substrate at least partially overlap.

In some exemplary embodiments, the orthographic projection of the third groove on the base substrate and the orthographic projection of the fourth groove on the base substrate overlap, a groove width of the third groove is 15 μm to 30 μm, and a groove depth of the third groove is 7 μm to 15 μm.

In some exemplary embodiments, an orthographic projection of the first electrode plate on the base substrate and an orthographic projection of the third electrode plate on the base substrate are configured to at least partially overlap. The first electrode plate and the third electrode plate are electrically connected through a metal hole structure, and the second electrode plate is provided with a first opening for avoiding the metal hole structure.

In some exemplary embodiments, the second electrode plate is provided with a plurality of first input terminals, and the third electrode plate is provided with a plurality of second input terminals. A plurality of notches on the first electrode plate and a plurality of notches on the third electrode plate are provided and correspond one-to-one with the first input terminals. Alternatively, a plurality of notches on the first electrode plate and a plurality of notches on the second electrode plate are provided and correspond one-to-one with the second input terminals.

In some exemplary embodiments, the display substrate further includes a buffer layer and a first insulating layer. The buffer layer is configured to cover a surface of the first conductive layer away from the base substrate, and the first insulating layer is configured to cover a surface of the second conductive layer away from the base substrate.

At least one embodiment of the present disclosure provides a display device including the display substrate described above.

At least one embodiment of the present disclosure provides a manufacturing method of a display substrate. The display substrate includes a display area and a bezel area located on at least one side of the display area, the bezel area including at least a gate driving circuit. The gate driving circuit includes at least a storage capacitor, a first signal line, and a second signal line, the storage capacitor including a first electrode plate, a second electrode plate, and a third electrode plate that are stacked.

The manufacturing method includes: forming a first conductive layer on a base substrate, the first electrode plate being disposed in the first conductive layer; forming a second conductive layer on a side of the first conductive layer away from the base substrate, the first signal line and the second electrode plate being disposed in the second conductive layer, the second electrode plate having a first input terminal connected to the first signal line; and forming a third conductive layer on a side of the second conductive layer away from the base substrate, the second signal line and the third electrode plate being disposed in the third conductive layer, the third electrode plate having a second input terminal connected to the second signal line.

Two of the first electrode plate, the second electrode plate, and the third electrode plate are provided with notches, and orthographic projections of the notches on the base substrate are configured to overlap with an orthographic projection of the first input terminal on the base substrate, or an orthographic projection of the second input terminal on the base substrate.

Other aspects of the present disclosure may be comprehended after the drawings and the detailed descriptions are read and understood.

### BRIEF DESCRIPTION OF DRAWINGS

FIG. 1 is a schematic diagram of a structure of a display device;

FIG. 2 is a schematic diagram of a planar structure of a display substrate;

FIG. 3 is a schematic diagram of a cross-sectional structure of a display substrate;

FIG. 4 is a schematic diagram of related storage capacitor structure maintenance;

FIG. 5 is a schematic diagram of a display substrate according to an exemplary embodiment of the present disclosure;

FIG. 6 is a schematic diagram of a cross-section along A-A in FIG. 5;

FIG. 7 is a partial schematic diagram of a gate driving circuit of FIG. 5;

FIG. 8 is a schematic diagram of a first conductive layer according to an exemplary embodiment of the present disclosure;

FIG. 9 is a schematic diagram of a first electrode plate in FIG. 8;

FIG. 10 is another schematic diagram of the first electrode plate in FIG. 8;

FIG. 11 is a schematic diagram of a buffer layer according to an exemplary embodiment of the present disclosure;

FIG. 12 is a schematic diagram of a second conductive layer according to an exemplary embodiment of the present disclosure;

FIG. 13 is a schematic diagram of a second electrode plate in FIG. 12;

FIG. 14 is another schematic diagram of the second electrode plate in FIG. 12;

FIG. 15 is a schematic diagram of a first insulating layer according to an exemplary embodiment of the present disclosure;

FIG. 16 is a schematic diagram of a first via according to an exemplary embodiment of the present disclosure;

FIG. 17 is a schematic diagram of a third conductive layer according to an exemplary embodiment of the present disclosure;

FIG. 18 is a schematic diagram of a third electrode plate in FIG. 17;

FIG. 19 is another schematic diagram of a third electrode plate;

FIG. 20 is an axonometric view of a storage capacitor according to an exemplary embodiment of the present disclosure;

FIG. 21 is a schematic cross-sectional view taken along a B-B direction of FIG. 5;

FIG. 22 is another schematic cross-sectional view of a storage capacitor of FIG. 5;

FIG. 23 is a schematic diagram of laser cutting of a storage capacitor according to an exemplary embodiment of the present disclosure;

FIG. 24 is a schematic diagram of another display substrate according to an exemplary embodiment of the present disclosure.

FIG. 25 is a schematic diagram of a storage capacitor in FIG. 24;

FIG. 26 is a schematic diagram of a second electrode plate in FIG. 25;

FIG. 27 is a schematic diagram of a third electrode plate in FIG. 25;

FIG. 28 is a schematic diagram of a first electrode plate in FIG. 25;

FIG. 29 is a schematic diagram of another storage capacitor according to an exemplary embodiment of the present disclosure.

FIG. 30 is a schematic diagram of a second electrode plate in FIG. 29; and

FIG. 31 is a schematic diagram of a first electrode plate in FIG. 29.

Reference signs are described as follows.

| | | |
|---|---|---|
| 10- base substrate; | 20- Drive circuit layer; | 30- Light-emitting |
| | | structure layer; |
| 40- Encapsulation | 21- Gate driving | 22- First conductive |
| structure layer; | circuit; | layer; |
| 23- Second conductive | 24- Third conductive | 25- Buffer layer; |
| layer; | layer; | |
| 26- First insulating | 50- Storage capacitor; | 51- First electrode |
| layer; | | plate; |
| 52- Second electrode | 53- Third electrode | 54- Metal hole structure; |
| plate; | plate; | |
| 511- First groove; | 512- First edge; | 513- Fifth edge; |
| 514- Third edge; | 515- Third groove; | 521- Sixth edge; |
| 522- Seventh edge; | 523- First opening; | 524- First position; |
| 525- First input | 526- Fourth edge; | 527- Fourth groove; |
| terminal; | | |
| 531- Second groove; | 532- Second edge; | 533- Eighth edge; |
| 534- Via metal | 535- Second position; | 536- Second input |
| structure; | | terminal; |
| 27- First via; | 100- Display area; | 200- Bonding area; |
| 300- Bezel area. | | |

### DETAILED DESCRIPTION

Embodiments of the present disclosure will be described in detail hereinafter with reference to the drawings. It is to be noted that the embodiments and features in the embodiments of the present disclosure may be randomly combined with each other if there is no conflict.

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation of the present disclosure is not limited to shapes, numerical values, or the like shown in the drawings.

Ordinal numerals “first”, “second”, “third” and the like in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulating layer” sometimes.

A triangle, rectangle, trapezoid, pentagon, or hexagon, or the like in the specification is not strictly defined, and it may be an approximate triangle, rectangle, trapezoid, pentagon, or hexagon, or the like. There may be some small deformations caused by tolerance, and there may be a chamfer, an arc edge, deformation, etc.

In an embodiment of the present disclosure, “about” means that a boundary is not strictly limited, and a value within a range of process and measurement error is allowed.

FIG. 1 is a schematic diagram of a structure of a display device. As shown in FIG. 1, the display device may include a timing controller, a data driver, a scan driver, a light-emitting driver, and a pixel array. The timing controller is connected to the data driver, the scan driver, and the light-emitting driver, respectively, the data driver is connected to a plurality of data signal lines (D1 to Dn) respectively, the scan driver is connected to a plurality of scan signal lines (S1 to Sm) respectively, and the light-emitting driver is connected to a plurality of light-emitting signal lines (E1 to Eo) respectively. The pixel array may include multiple sub-pixels Pxij, wherein i and j may be natural numbers. At least one sub-pixel Pxij may include a circuit unit and a light-emitting device connected to the circuit unit, and the circuit unit may include a pixel drive circuit which is connected with a scan signal line, a light-emitting signal line and a data signal line. In an exemplary embodiment, the timing controller may provide the data driver with a grayscale value and a control signal which are suitable for a specification of the data driver, provide the scan driver with a clock signal and a scan start signal and the like which are suitable for a specification of the scan driver, and provide the light-emitting driver with a clock signal and an emission stop signal and the like which are suitable for a specification of the light-emitting driver. The data driver may generate data voltages to be provided to the data signal lines D1, D2, D3, . . . , and Dn using the grayscale value and the control signal that are received from the timing controller. For example, the data driver may sample the grayscale value by using the clock signal and apply a data voltage corresponding to the grayscale value to the data signal lines D1 to Dn by taking a unit row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light-emitting driver may generate an emission signal to be provided to the light-emitting signal lines E1, E2, E3, . . . , and Eo by receiving a clock signal, an emission stop signal and the like from the timing controller. For example, the light-emitting driver may sequentially provide an emission signal with an off-level pulse to the light-emitting signal lines E1 to Eo. For example, the light-emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be arranged on a display substrate.

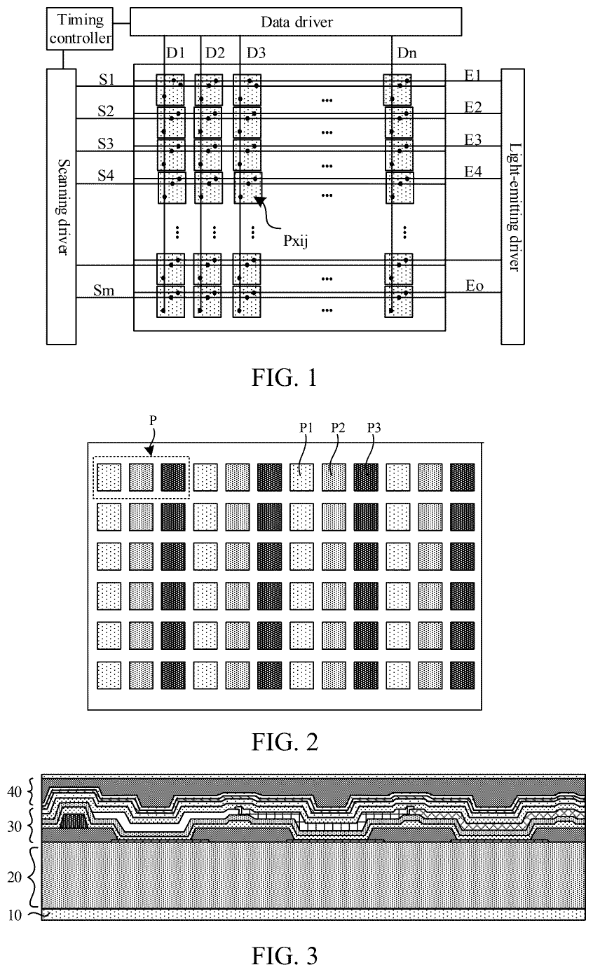

FIG. 2 is a schematic diagram of a planar structure of a display substrate. As shown in FIG. 2, the display substrate may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light-emitting device. The circuit unit may at least include a pixel drive circuit, the pixel drive circuit is connected to a scan signal line, a light-emitting signal line, and a data signal line respectively, and the pixel drive circuit is configured to receive a data voltage transmitted by the data signal line and output a corresponding current to the light-emitting device under control of the scan signal line and the light-emitting signal line. The light-emitting device in each sub-pixel is connected to a pixel drive circuit of a sub-pixel where the light-emitting device is located, and is configured to emit light with corresponding brightness in response to a current output by the pixel drive circuit of the sub-pixel where the light-emitting device is located.

In an exemplary embodiment, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be arranged horizontally side by side, vertically side by side, or in a Chinese character “ [symbol] ” arrangement, etc., which is not limited here in the present disclosure.

In an exemplary embodiment, a pixel unit may include four sub-pixels, and the four sub-pixels may be arranged horizontally side by side, vertically side by side, or in a manner of forming a square, which is not limited here in the present disclosure.

FIG. 3 is a schematic diagram of a cross-sectional structure of a display substrate, which illustrates a structure of four sub-pixels. As shown in FIG. 3, in a plane perpendicular to the display substrate, the display substrate may include a drive circuit layer 20 arranged on a base substrate 10, a light-emitting structure layer 30 arranged on a side of the drive circuit layer 20 away from the base substrate 10, and an encapsulation structure layer 40 arranged on a side of the light-emitting structure layer 30 away from the base substrate 10. In some possible implementations, the display substrate may include another film layer, such as a touch structure layer, which is not limited here in the present disclosure.

In an exemplary implementation, the base substrate 10 may be a flexible base substrate, or may be a rigid base substrate. The drive circuit layer 20 may include a plurality of circuit units, each of which may at least include a pixel drive circuit composed of a plurality of transistors and a storage capacitor. The light-emitting structure layer 30 may include a plurality of light-emitting devices, and each light-emitting device may at least include an anode, a pixel definition layer, an organic light-emitting layer, and a cathode. The anode is connected with the pixel drive circuit, the organic light-emitting layer is connected with the anode, the cathode is connected with the organic light-emitting layer, and the organic light-emitting layer emits light of a corresponding color under driving of the anode and the cathode. The encapsulation structure layer 40 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a stacked structure of inorganic material/organic material/inorganic material and ensure that external moisture cannot enter the light-emitting structure layer 30.

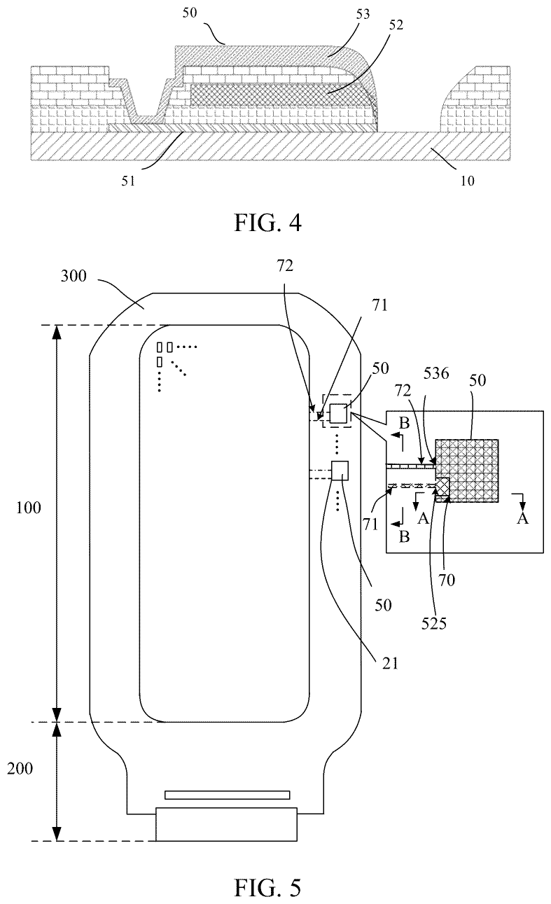

At present, during the operation of the gate driving circuit of the related display substrate, a foreign matter falls off to the capacitor area or electrostatic discharge (ESD) occurs, which will cause the storage capacitor to fail and turn it into a problematic capacitor. FIG. 4 is a schematic diagram of related storage capacitor structure maintenance. As shown in FIG. 4, the storage capacitor 50 includes a first electrode plate (Shield) 51, a second electrode plate (Gate) 52 and a third electrode plate (SD) 53. The second electrode plate 52 is located between the third electrode plate 53 and the first electrode plate 51, and when a foreign matter falls off, the second electrode plate (Gate) 52 and the third electrode plate (SD) 53 will be short-circuited, resulting in a problematic capacitor, and the charge cannot be stored or discharged. The transistor (not shown in the figure) of the gate driving circuit 21 cannot be turned on and transmitted normally, and the display area of the display substrate cannot get the gate signal, forming a penetrating Y dark line. Usually, a laser is used to cut off the gate metal wire connected to the problematic capacitor, and cut off the connection between the problematic capacitor and the adjacent normal capacitor. Through research conducted by the inventor of the present application, it is found that the laser radiation area generated by maintenance is large, and the edge of the normal storage capacitor adjacent to the problematic capacitor is often cut during maintenance process. As shown in FIG. 4, the edge of the storage capacitor 50 is cut by laser, and the third electrode plate 53 and the second electrode plate 52 will be cut at the same time. The thermal radiation of laser can make the third electrode plate 53 and the second electrode plate 52 short-circuited after melting, resulting in the failure of the adjacent storage capacitors, and making more storage capacitors unable to work normally, and the maintenance effect is poor.

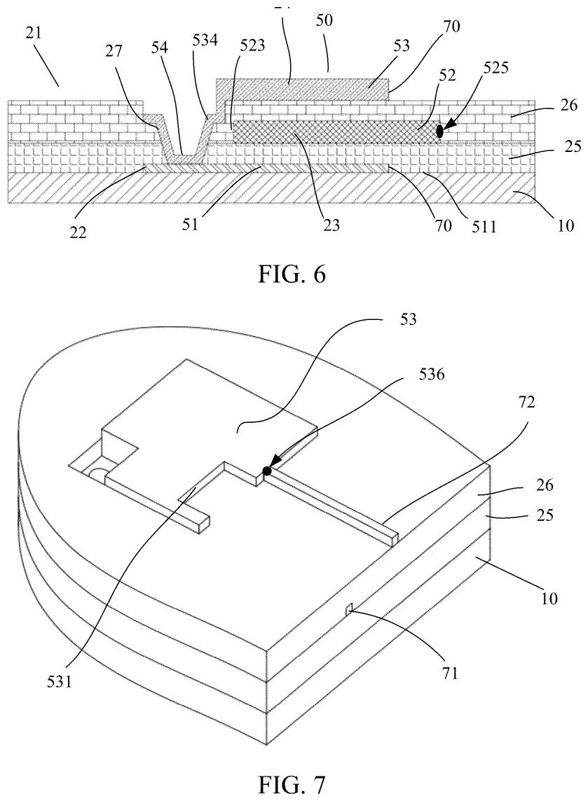

FIG. 5 is a schematic diagram of a display substrate according to an exemplary embodiment of the present disclosure, FIG. 6 is a schematic diagram of a cross-section along A-A in FIG. 5, and FIG. 7 is a partial schematic diagram of a gate driving circuit of FIG. 5. An embodiment of the present disclosure provides a display substrate, as shown in FIGS. 5, 6, and 7. The display substrate may include a display area 100 and a bezel area 300 located on at least one side of the display area 100. The bezel area 300 may include at least a gate driving circuit 21 which includes at least a storage capacitor 50, a first signal line 71, and a second signal line 72. The storage capacitor 50 includes a first electrode plate 51, a second electrode plate 52, and a third electrode plate 53 that are stacked. In a direction perpendicular to the display substrate, the display substrate includes a first conductive layer 22, a second conductive layer 23, and a third conductive layer 24 sequentially disposed on the base substrate 10 along a direction away from the base substrate 10. The first electrode plate 51 is disposed in the first conductive layer 22. The first signal line 71 and the second electrode plate 52 are disposed in the second conductive layer 23, and the second electrode plate 52 has a first input terminal 525 connected to the first signal line 71. The second signal line 72 and the third electrode plate 53 are disposed in the third conductive layer 24, and the third electrode plate 53 has a second input terminal 536 connected to the second signal line 72. Two of the first electrode plate 51, the second electrode plate 52, and the third electrode plate 53 are provided with notches. Orthographic projections of the notches 70 on the base substrate 10 are configured to overlap with an orthographic projection of the first input terminal 525 on the base substrate 10, or to overlap with the orthographic projection of the second input terminal 536 on the base substrate 10. In some exemplary embodiments, both the first electrode plate 51 and the third electrode plate 53 are provided with notches 70 corresponding to the first input terminal 525 in a direction perpendicular to the base substrate 10. Both the first electrode plate 51 and the third electrode plate 53 are staggered from the first input terminal 525, both orthographic projections of the first electrode plate 51 and the third electrode plate 53 on the base substrate 10 do not overlap with the orthographic projections of the first input terminal 525 on the base substrate 10. The orthographic projections of the notches 70 on the base substrate 10 overlap with the orthographic projection of the first input terminal 525 on the base substrate 10, but it is not limited thereto. For example, both the first electrode plate 51 and the second electrode plate 52 are provided with notches 70 corresponding to the second input terminal 536 in a direction perpendicular to the base substrate 10. Both the first electrode plate 51 and the second electrode plate 52 are staggered from the second input terminal 536. The orthographic projections of the first electrode plate 51 and the second electrode plate 52 on the base substrate 10 do not overlap with an orthographic projection of the second input terminal 536 on the base substrate 10. The orthographic projections of the notches 70 on the base substrate 10 overlap with the orthographic projection of the second input terminal 536 on the base substrate 10.

In some exemplary embodiments, as shown in FIGS. 5, 6, and 7, a circumferential edge of the first electrode plate 51 may be provided with a first groove 511 recessed inward, and the first groove 511 may extend in a direction perpendicular to the base substrate 10 and may penetrate the first electrode plate 51. A circumferential edge of the third electrode plate 53 may be provided with a second groove 531 recessed inward, and the second groove 531 may extend in a direction perpendicular to the base substrate 10 and may penetrate the third electrode plate 53. Orthographic projections of the first groove 511 and the second groove 531 on the base substrate 10 may at least partially overlap.

In some exemplary embodiments, as shown in FIGS. 5, 6, and 7, an orthographic projection of the first groove 511 on the base substrate 10 may completely overlap with an orthographic projection of the second groove 531 on the base substrate 10, and both of the first groove 511 and the second groove 531 may be provided as rectangular grooves, but it is not limited thereto. For example, both of the first groove 511 and the second groove 531 may be arc-shaped grooves.

In some exemplary embodiments, as shown in FIGS. 5, 6, and 7, a groove shape, a groove width, and a groove depth of the first groove 511 and the second groove 531 may all be the same. The groove width of the first groove 511 and the groove width of the second groove 531 may both be set to be 15 μm to 30 μm, and the groove depth of the first groove 511 and the groove depth of the second groove 531 may both be set to be 7 μm to 15 μm.

In some exemplary embodiments, as shown in FIGS. 5, 6, and 7, the display substrate further includes a buffer layer 25, a first insulating layer 26, and a passivation layer (not shown in the figure). The buffer layer 25 may be located at least between the first electrode plate 51 and the second electrode plate 52, and within the first groove 511. The first insulating layer 26 may be located at least between the second electrode plate 52 and the third electrode plate 53. The passivation layer (not shown in the figure) is located at least on a surface of the third electrode plate 53 away from the second electrode plate 52 and within the second groove 531.

In some exemplary embodiments, as shown in FIGS. 5, 6, and 7, the orthographic projection of the first electrode plate 51 on the base substrate 10 and the orthographic projection of the third electrode plate 53 on the base substrate 10 may at least partially overlap. In this example, the orthographic projection of the first electrode plate 51 on the base substrate 10 and the orthographic projection of the third electrode plate 53 on the base substrate 10 completely overlap. The first electrode plate 51 and the third electrode plate 53 can be electrically connected through a metal hole structure 54, and the second electrode plate 52 is provided with a first opening 523 for avoiding the metal hole structure 54.

Exemplary description is made below through a manufacturing process of the display substrate according to the exemplary embodiment. A “patterning process” mentioned in the present disclosure includes treatments such as deposition of a film layer, photoresist coating on a film layer, mask exposure, development, etching, and photoresist stripping for a metal material, an inorganic material, or a transparent conductive material, and includes treatments such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B is within a range of an orthographic projection of A” or “an orthographic projection of A contains an orthographic projection of B” means that a boundary of the orthographic projection of B falls within a range of a boundary of the orthographic projection of A, or the boundary of the orthographic projection of A coincides with the boundary of the orthographic projection of B.

In an exemplary implementation, a preparation process of the display substrate may include following operations.

### (1) Preparing a First Conductive Layer on a Base Substrate 10.

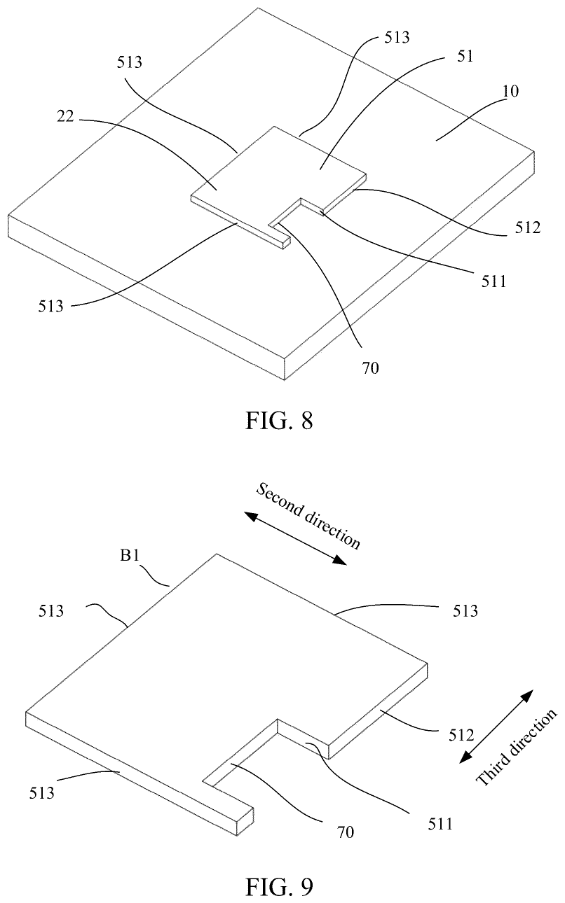

In some exemplary embodiments, preparing the first conductive layer on the base substrate may include: first depositing a first conductive thin film on the base substrate 10, then coating a photoresist on the first conductive thin film, and etching the first conductive thin film after exposure and development to form a shielding first conductive layer 22, which includes at least a first electrode plate 51, as shown in FIG. 8.

In some exemplary embodiments, a mask used to form the first conductive layer 22 needs to be designed according to the first electrode plate 51 having the first groove 511. The pattern of the photoresist after exposure and development by using the mask has an exposed area and an unexposed area, the photoresist remains in the exposed area, and the photoresist in the unexposed area is removed, to expose a surface of the first conductive thin film. The etching process removes the first conductive thin film of the unexposed area, retains the first conductive thin film of the exposed area, and forms at least the first electrode plate 51 having the first groove 511.

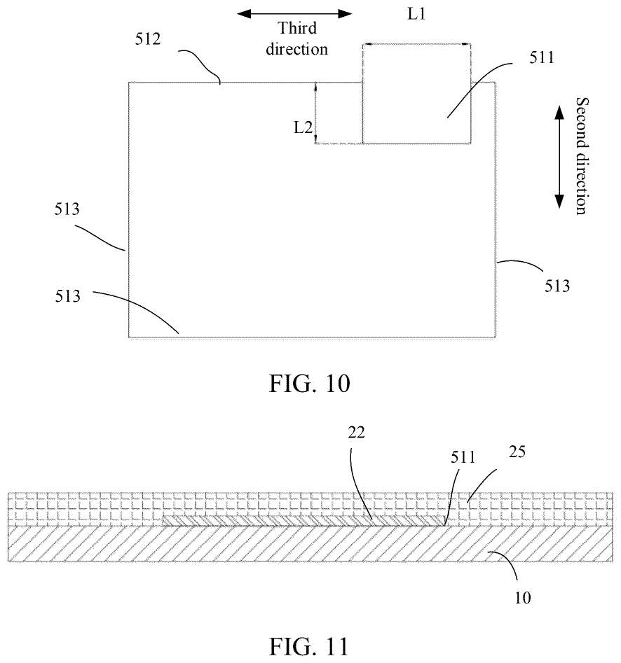

FIG. 9 is a schematic diagram of a first electrode plate in FIG. 8, and FIG. 10 is another schematic diagram of a first electrode plate in FIG. 8. In some exemplary embodiments, as shown in FIGS. 8, 9, and 10, the first electrode plate 51 may be provided on the base substrate 10, and a material of the first electrode plate 51 may be a metal material, such as copper (Cu) or aluminum (Al), etc. The first electrode plate 51 may be a rectangular plate shape, and a circumferential edge B1 of the first electrode plate 51 may be an edge surrounding a geometric center of the first electrode plate 51 in a plane parallel to the base substrate 10. The circumferential edge B1 of the first electrode plate 51 may include one first edge 512 and three fifth edges 513 which may form a rectangular ring. The first edge 512 is located at one end of the first electrode plate 51 in a second direction and may extend in a third direction. One of the fifth edges 513 is located at the other end in the second direction and may extend in the third direction, and the other two of the fifth edges 513 may respectively be located at the two ends of the first electrode plate 51 in the third direction and may both extend in the second direction. The second direction is perpendicular to the third direction, and both the second direction and the third direction are parallel to the base substrate 10. The first edge 512 may be provided with a first groove 511 penetrating the first electrode plate 51 in a direction perpendicular to the base substrate 10, and the first groove 511 may be formed by recessing the first edge 512 toward an inner side of the first electrode plate 51. The inner side of the first electrode plate 51 may be a portion of the first electrode plate 51 close to the geometric center thereof, and the first groove 511 constitutes the notch 70. The first groove 511 may be recessed toward the opposite fifth edge 513. The first groove 511 may be a rectangular groove, but it is not limited thereto. For example, the first groove 511 may be an arc-shaped groove or an irregular pattern groove, or the like. The groove width of the first groove 511 may be the largest dimension occupied by the first groove 511 in the third direction, that is, L1, and the groove depth of the first groove 511 may be the largest dimension occupied by the first groove 511 in the second direction, that is, L2. In some exemplary embodiments, the groove width L1 of the first groove 511 may be 20 μm, and the groove depth L2 of the first groove 511 may be 10 μm, but it is not limited thereto. The groove width L1 of the first groove 511 may be another value in the range of 15 μm to 30 μm, and the groove depth L2 of the first groove 511 may be another value in the range of 7 μm to 15 μm.

### (2) Sequentially Preparing a Buffer Layer, an Active Layer and a Gate Insulating Layer.

In some exemplary embodiments, sequentially preparing the buffer layer and the active layer may include first depositing a thin film of an inorganic material on the base substrate 10 having the first conductive layer 22 to form a buffer layer 25. Then, an active layer film is deposited on the buffer layer 25, and the active layer film is treated to form an active layer. Subsequently, a gate insulating layer film is deposited on the base substrate 10 having the active layer, and the gate insulating layer film is treated to form a gate insulating layer.

FIG. 11 is a schematic diagram of a buffer layer according to an exemplary embodiment of the present disclosure. In some exemplary embodiments, as shown in FIG. 11, the buffer layer 25 covers the first conductive layer 22 and also covers a portion of the base substrate 10 where the first conductive layer 22 is not provided. In this example, a portion of the buffer layer 25 may be formed in the first groove 511 of the first electrode plate 51. The material of the buffer layer 25 may be an inorganic insulating material, specifically any one or more of silicon oxide (SiOx), silicon nitride (SiNx), and silicon oxynitride (SiON), and may be a single layer, a plurality of layers, or a composite layer, and the buffer layer 25 can improve the water and oxygen resistance of the base substrate 10.

In some exemplary embodiments, after the active layer film is deposited on the buffer layer 25, the active layer film may be coated with a photoresist, and etched after exposure and development to form an active layer pattern to obtain an active layer (not shown in the figure). After the gate insulating layer film is deposited on the base substrate 10 having the active layer, the gate insulating layer film may be coated with a photoresist, and then etched after exposure and development to form a gate insulating layer (not shown in the figure).

### (3) Preparing a Second Conductive Layer.

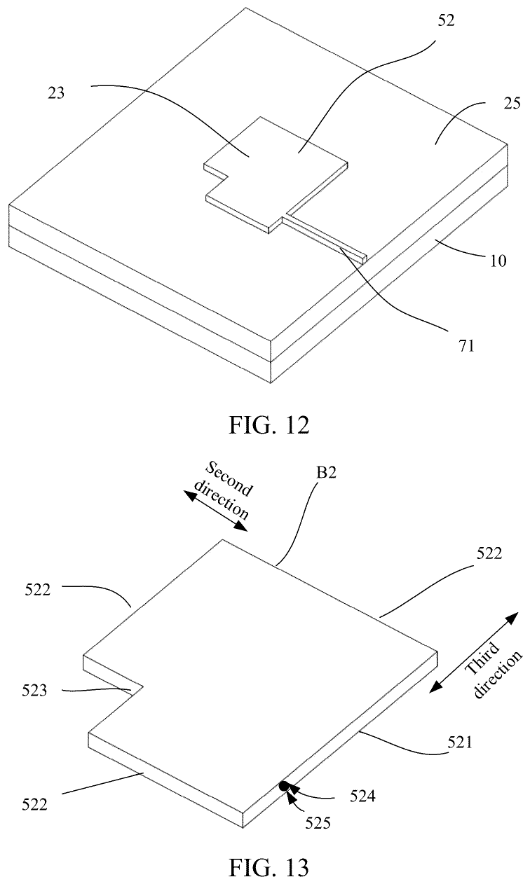

In some exemplary embodiments, preparing the second conductive layer includes: depositing a second conductive thin film on the base substrate 10 having the gate insulating layer and the buffer layer 25, coating a photoresist on the second conductive thin film, and etching the second conductive thin film after exposure and development to form a second conductive layer 23 which includes at least a second electrode plate 52 and a first signal line 71, as shown in FIG. 12.

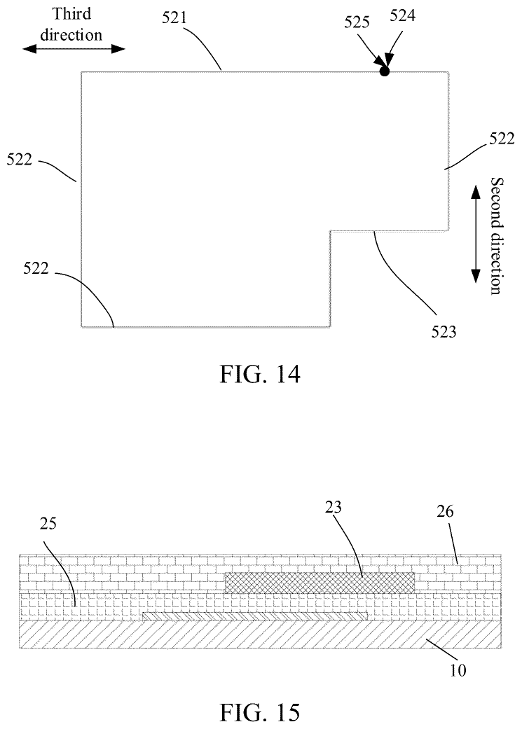

FIG. 13 is a schematic diagram of a second electrode plate in FIG. 12, and FIG. 14 is another schematic diagram of a second electrode plate in FIG. 12. In some exemplary embodiments, as shown in FIGS. 12, 13, and 14, the second electrode plate 52 may be provided on a surface of the buffer layer 25 away from the base substrate 10, the material of the second electrode plate 52 may be a metal material, such as copper (Cu) or aluminum (Al), and the like, and the second electrode plate 52 may be used as a gate metal electrode. A circumferential edge B2 of the second electrode plate 52 may be an edge surrounding a geometric center of the second electrode plate 52 in a plane parallel to the base substrate 10. The circumferential edge B2 of the second electrode plate 52 may include one sixth edge 521 and three seventh edges 522. The sixth edge 521 is located at one end of the second electrode plate 52 in the second direction and extends in the third direction. One of the seventh edges 522 is located at the other end in the second direction and extends in the third direction, and the other two of the seventh edges 522 may be respectively located at both ends of the second electrode plate 52 in the third direction and extend in the second direction. The second direction is perpendicular to the third direction, and the second and third directions are both parallel to the base substrate 10. The sixth edge 521 may be provided with a first position 524 to which one end of the first signal line 71 is connected, and the first position 524 serves as a first input terminal 525 of the second electrode plate 52. One first opening 523 is provided at the connection position of the two seventh edges 522, and the first opening 523 may be rectangular, but it is not limited thereto. For example, the shape of the first opening 523 may be triangular or the like, and for example, the position of the first opening 523 may be located at another position of the circumferential edge B2 of the second electrode plate 52. In some exemplary embodiments, the first signal line 71 may be in the same layer as the second electrode plate 52, one end of the first signal line 71 is connected to the first input terminal 525, the material of the first signal line 71 may be the same as the material of the second electrode plate 52, and the first signal line 71 may serve as a gate metal line.

### (4) Preparing a First Insulating Layer.

In some exemplary embodiments, preparing the first insulating layer includes: first depositing an interlayer dielectric thin film on the base substrate where the second conductive layer 23 is formed, the interlayer dielectric thin film covering the gate metal layer, the gate insulating layer, and the active layer, and the interlayer dielectric thin film constituting the first insulating layer 26, as shown in FIG. 14; then, forming vias in the first insulating layer 26 and the buffer layer 25. The vias include at least a first via 27 for exposing the first electrode plate 51, as shown in FIG. 15.

FIG. 15 is a schematic diagram of a first insulating layer according to an exemplary embodiment of the present disclosure. In some exemplary embodiments, as shown in FIG. 15, the first insulating layer 26 covers a surface of the second conductive layer 23 away from the base substrate 10, and also covers the exposed portion of the buffer layer 25 away from the base substrate 10. The material of the first insulating layer 26 may be an inorganic insulating material, specifically any one or more of silicon oxide (SiOx), silicon nitride (SiNx), and silicon oxynitride (SiON), and may be a single layer, a plurality of layers, or a composite layer.

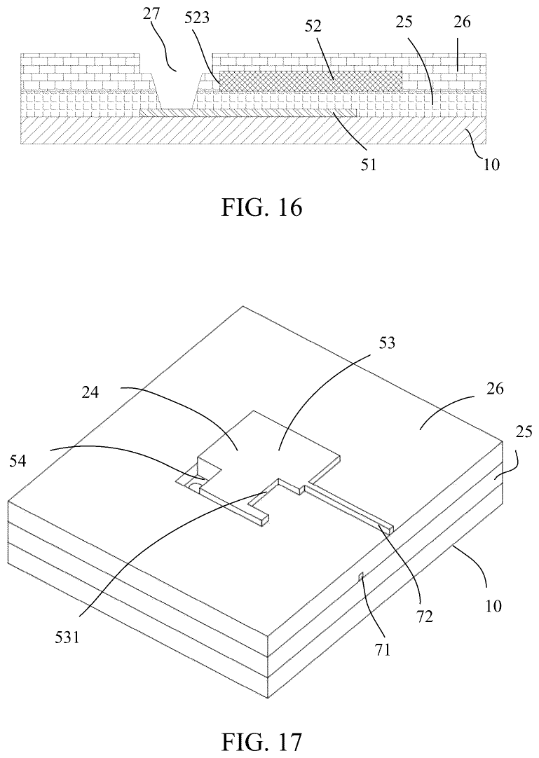

FIG. 16 is a schematic diagram of a first via according to an exemplary embodiment of the present disclosure. In some exemplary embodiments, as shown in FIG. 16, the first via 27 extends from a surface of the first insulating layer 26 away from the base substrate 10 to a surface of the first electrode plate 51 away from the base substrate 10. The first via 27 corresponds to the first opening 523 in a direction perpendicular to the base substrate 10. When processing the first via 27, a hole may firstly be opened in the first insulating layer 26 to expose a portion of the surface of the buffer layer 25 away from the base substrate 10, and a via may be continuously opened in the exposed buffer layer 25 to expose a portion of the surface of the first electrode plate 51 away from the base substrate 10 to form the first via 27. In addition to the first via, there are other vias, such as vias for exposing the active layer. When processing the vias, a hole needs to be opened in the first insulating layer 26, extending all the way to a surface of the active layer away from the base substrate 10.

### (5) Preparing a Third Conductive Layer.

In some exemplary embodiments, preparing the third conductive layer includes: depositing a third conductive thin film on the base substrate 10 having the first insulating layer 26, coating a photoresist on the third conductive thin film, and etching the third conductive thin film after exposure and development to form a third conductive layer 24 which includes at least a third electrode plate 53 and a second signal line 72, as shown in FIG. 17.

In some exemplary embodiments, a mask used to form the third conductive layer 24 needs to be designed according to the third electrode plate 53 having the second groove 531. The pattern of the photoresist after exposure and development by using the mask has an exposed area and an unexposed area, the photoresist remains in the exposed area, and the photoresist in the unexposed area is removed, to expose a surface of the third conductive film. The etching process removes the third conductive film of the unexposed area, retains the third conductive film of the exposed area, and forms at least the third electrode plate 53 having the second groove 531.

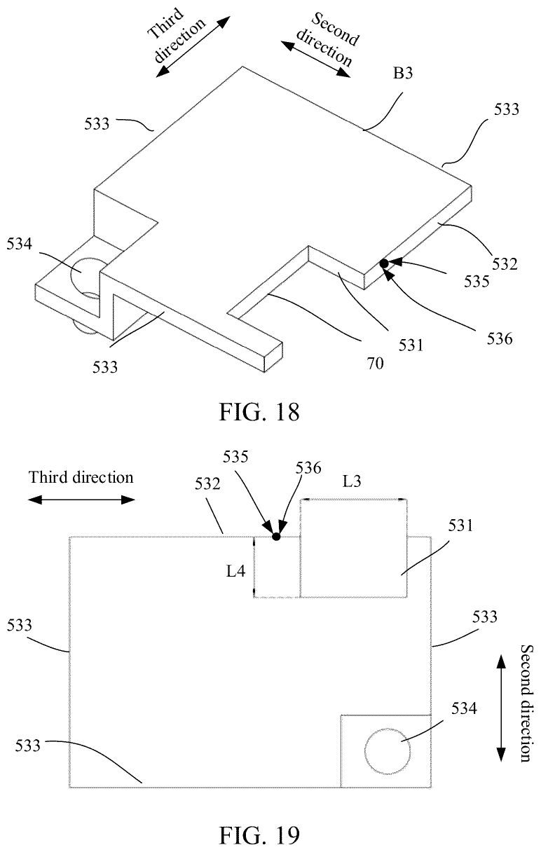

FIG. 18 is a schematic diagram of a third electrode plate in FIG. 17, and FIG. 19 is another schematic diagram of a third electrode plate in FIG. 17. In some exemplary embodiments, as shown in FIGS. 17, 18, and 19, the third electrode plate 53 may be provided on a surface of the first insulating layer 26 away from the base substrate 10, the material of the third electrode plate 53 may be a metal material, such as copper (Cu) or aluminum (Al), etc., and the third electrode plate 53 may be used as a source-drain electrode. A circumferential edge B3 of the third electrode plate 53 may be an edge surrounding a geometric center of the third electrode plate 53 in a plane parallel to the base substrate 10. The circumferential edge B3 of the third electrode plate 53 may include one second edge 532 and three eighth edges 533. The second edge 532 is located at one end of the third electrode plate 53 in the second direction and extends in the third direction. One of the eighth edges 533 is located at the other end in the second direction and extends in the third direction, and the other two of the eighth edges 533 may respectively be located at both ends of the third electrode plate 53 in the third direction and both extend in the second direction. The second direction is perpendicular to the third direction, and both the second direction and the third direction are parallel to the base substrate 10. The second edge 532 may be provided with a second groove 531 penetrating the third electrode plate 53 in a direction perpendicular to the base substrate 10, and the second groove 531 may be formed by recessing the second edge 532 toward an inner side of the third electrode plate 53. The inner side of the third electrode plate 53 may be a portion of the third electrode plate 53 close to its geometric center, and the second groove 531 constitutes a notch 70. The second groove 531 may be recessed toward the opposite eighth edge 533. The second groove 531 may be a rectangular groove, but it is not limited thereto. For example, the second groove 531 may be an arc-shaped groove or an irregular pattern groove, or the like. The groove width of the second groove 531 may be the largest dimension occupied by the second groove 531 in the third direction, that is, L3, and the groove depth of the second groove 531 may be the largest dimension occupied by the second groove 531 in the second direction, that is, L4. In some exemplary embodiments, the groove width L3 of the second groove 531 may be 20 μm, and the groove depth L4 of the second groove 531 may be 10 μm, but it is not limited thereto. The groove width L3 of the second groove 531 may be another value in the range of 15 μm to 30 μm, and the groove depth L4 of the second groove 531 may be another value in the range of 7 μm to 15 μm.

In some exemplary embodiments, as shown in FIGS. 17, 18, and 19, a second position 535 may be provided on the second edge 532, and one end of the first signal line 72 is connected to the second position 535, and the second position 535 serves as the second input terminal 536, but it is not limited thereto. For example, the second position 535 may be located on the eighth edge 533. A via metal structure 534 is provided at the connection position of the two eighth edges 533, but it is not limited thereto. For example, the via metal structure 534 may be located at other positions of the circumferential edge B 3 of the third electrode plate 53. In some exemplary embodiments, the second signal line 72 may be in the same layer as the third electrode plate 53, one end of the second signal line 72 is connected to the second input terminal 536, the material of the second signal line 72 may be the same as the material of the third electrode plate 53, and the second signal line 72 may be used as a source-drain metal line.

After the third conductive layer 24 is prepared, the storage capacitor 50, the first signal line 71, and the second signal line 72 are all formed. FIG. 5 is a schematic diagram of a display substrate according to an exemplary embodiment of the present disclosure, and FIG. 6 is a schematic diagram of a cross-section in the A-A direction in FIG. 5. In some exemplary embodiments, as shown in FIGS. 5 and 6, the storage capacitor 50 may include a first electrode plate 51, a second electrode plate 52, and a third electrode plate 53 which are sequentially stacked in a direction perpendicular to the base substrate 10. The first electrode plate 51 may be disposed on the base substrate 10, and the second electrode plate 52 may have a first input terminal 525 for connecting with a first signal line. Both the first electrode plate 51 and the third electrode plate 53 are provided with a notch 70 corresponding to the first input terminal 525 in a direction perpendicular to the base substrate, so that both the first electrode plate 51 and the third electrode plate 53 are staggered from the first input terminal 525.

In some exemplary embodiments, as shown in FIGS. 5 and 6, the orthographic projection of the first electrode plate 51 on the base substrate 10 may overlap with the orthographic projection of the third electrode plate 53 on the base substrate 10, and the first electrode plate 51 and the third electrode plate 53 may be electrically connected by a metal hole structure 54. The metal hole structure 54 includes a first via 27 and a via metal structure 534 located within the first via 27. The via metal structure 534 may extend to a surface of the first electrode plate 51 away from the base substrate 10. The first opening 523 of the second electrode plate 52 is disposed corresponding to the metal hole structure 54 such that the second electrode plate 52 avoids the metal hole structure 54.

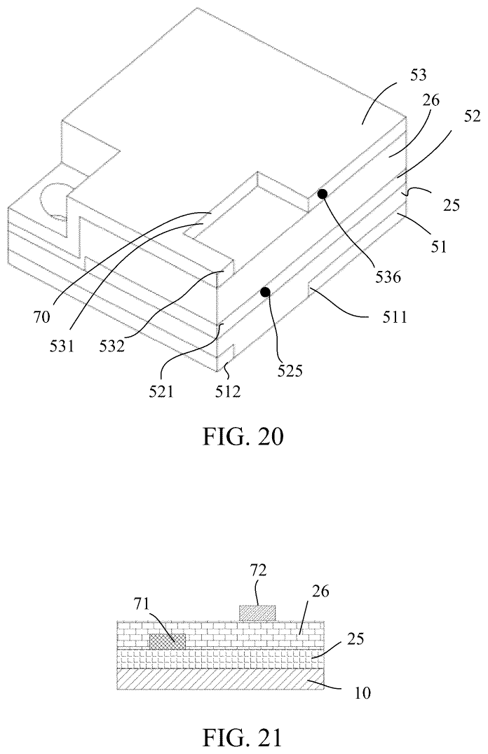

FIG. 20 is an axonometric view of a storage capacitor according to an exemplary embodiment of the present disclosure. In some exemplary embodiments, as shown in FIGS. 6 and 20, in some exemplary embodiments, the circumferential edge of the first electrode plate 51 may include a first edge 512 provided with a first groove 511, and the first groove 511 constitutes a notch 70. The circumferential edge of the third electrode plate 53 may include a second edge 532 provided with a second groove 531, and the second groove 531 constitutes another notch 70. A circumferential edge of the second electrode plate 52 may include a sixth edge 521 provided with a first input terminal 525. The first groove 511, the second groove 531, and the first input terminal 525 correspond in a direction perpendicular to the base substrate 10, so that the first input terminal 525 may be staggered from both the first electrode plate 51 and the third electrode plate 53. The first edge 512, the second edge 532, and the sixth edge 521 are flush in the direction perpendicular to the base substrate 10, the groove shapes of the first groove 511 and the second groove 531 are the same, and the groove depth and groove width of the first groove 511 and the second groove 531 are the same. The orthographic projection of the first groove 511 on the base substrate 10 and the orthographic projection of the second groove 531 on the base substrate 10 overlap, and the orthographic projection of the first input terminal 525 on the base substrate 10 is approximately at the position of the orthographic projection of a groove opening of the first groove 511 on the base substrate 10, but it is not limited to this. For example, the first edge 512, the second edge 532 and the sixth edge 521 are staggered in the direction perpendicular to the base substrate 10. For another example, at least one of the groove shapes, groove depths and groove widths of the first groove 511 and the second groove 531 are inconsistent, so that the orthographic projection of the first groove 511 on the base substrate 10 and the orthographic projection of the second groove 531 on the base substrate 10 partially overlap. The display substrate further includes a buffer layer 25, a first insulating layer 26, and a passivation layer (not shown in the figure). The buffer layer 25 is located at least between the first electrode plate 51 and the second electrode plate 52 and also within the first groove 511, the first insulating layer 26 is located at least between the second electrode plate 52 and the third electrode plate 53, and the passivation layer is located at least on a surface of the third electrode plate 53 remote from the second electrode plate 52 and within the second groove 531.

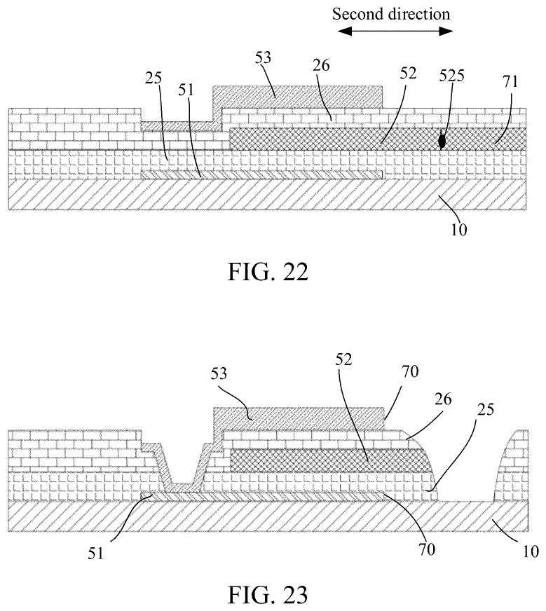

FIG. 21 is a schematic cross-sectional view taken along a B-B direction of FIG. 5, and FIG. 22 is another schematic cross-sectional view of a storage capacitor in FIG. 5. In some exemplary embodiments, as shown in FIGS. 5, 21, and 22, the first signal line 71 and the second signal line 72 extend in a same direction, the first signal line 71 extends in the second direction, and one end of the first signal line 71 is connected to the first input terminal 525. The first signal line 71 and the second signal line 72 are not arranged in a same layer, and the first signal line 71 is located on a surface of the buffer layer 25 away from the base substrate 10, and the second signal line 72 is located on a surface of the first insulating layer 26 away from the base substrate 10. The first signal line 71 and the second signal line 72 are staggered in the direction perpendicular to the base substrate 10, so that the first input terminal 525 and the second input terminal are also arranged in a staggered manner in the direction perpendicular to the base substrate 10.

FIG. 23 is a schematic diagram of laser cutting of a storage capacitor according to an exemplary embodiment of the present disclosure. In some exemplary embodiments, as shown in FIG. 23, when laser is used for maintenance, a first signal line connected to a problematic capacitor is cut, possibly to a position near a first position 524 of the storage capacitor, continuing to cut downward in a direction perpendicular to the base substrate 10, and to the base substrate 10. In particular, the cutting position of the laser corresponds to the notch 70, so that only the first signal line and a small part of the second electrode plate 52 are cut off, and the third electrode plate 53 and the first electrode plate 51 are not cut. Even if the part of the second electrode plate 52 that has been cut is melted, it will not come into contact with the first electrode plate 51, so that the short circuit can be avoided, normal use can be achieved, and the success rate of maintenance can be improved.

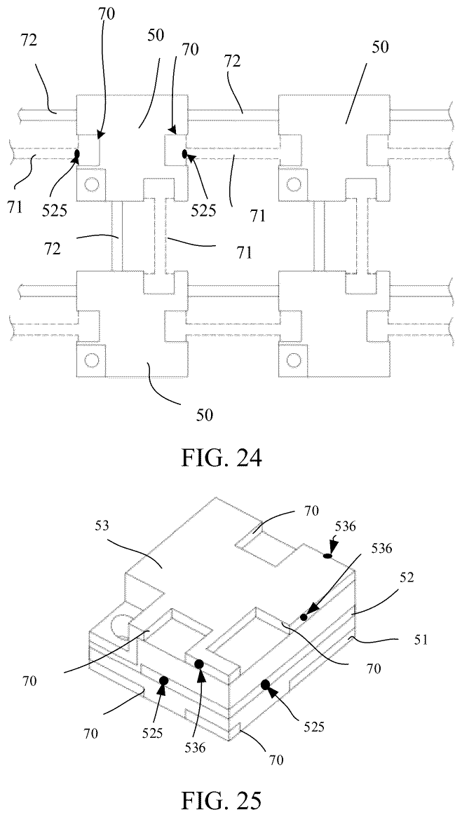

FIG. 24 is a schematic diagram of another display substrate according to an exemplary embodiment of the present disclosure, and FIG. 25 is a schematic diagram of a storage capacitor in FIG. 24. In some exemplary embodiments, as shown in FIGS. 24 and 25, the storage capacitor 50 may have a plurality of first input terminals 525 and a plurality of second input terminals 536, and the storage capacitor 50 is connected to a plurality of adjacent other storage capacitors 50 through a first signal line 71 and a second signal line 72. In this example, the storage capacitor 50 may have three first input terminals 525 and three second input terminals 536, and the storage capacitor 50 is connected with three adjacent storage capacitors 50.

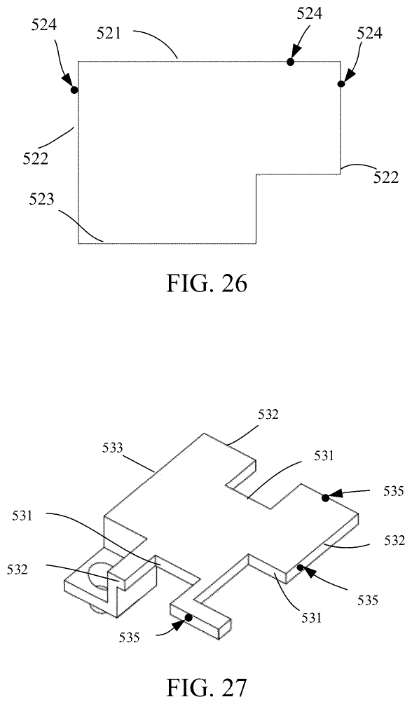

FIG. 26 is a schematic diagram of a second electrode plate in FIG. 25. In some exemplary embodiments, as shown in FIGS. 25 and 26, the circumferential edge of the second electrode plate 52 may include three sixth edges 521 and one seventh edge 522, and each sixth edge 521 may have a first position 524 forming three first input terminals 525, but it is not limited thereto. For example, the circumferential edge of the second electrode plate 52 may have two first positions 524 forming two first input terminals 525.

FIG. 27 is a schematic diagram of a third electrode plate in FIG. 25. In some exemplary embodiments, as shown in FIGS. 25 and 27, the circumferential edge of the third electrode plate 53 may include three second edges 532 and one eighth edge 533. Each second edge 532 may have one second groove 531 to form three notches 70, the three second grooves 531 may all be rectangular grooves, and the groove depth and groove width of the three second grooves 531 may all be the same, but it is not limited thereto. For example, the groove shapes of the three second grooves 531 may be different, and for example, the groove depth and groove width of the three second grooves 531 may be different. Each second edge 532 may have one second location 535 forming three second input terminals 536.

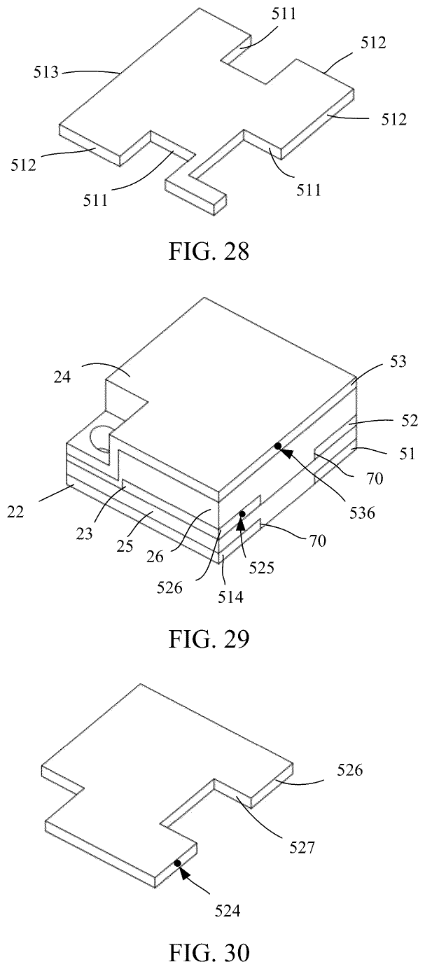

FIG. 28 is a schematic diagram of a first electrode plate in FIG. 25. In some exemplary embodiments, as shown in FIGS. 25 and 28, the circumferential edge of the first electrode plate 51 may include three first edges 512 and one fifth edge 513. Each first edge 512 may have one first groove 511 to form three notches 70, the three first grooves 511 may all be rectangular grooves, and the groove depth and groove width of the three first grooves 511 may all be the same, but it is not limited thereto. For example, the groove shapes of the three first grooves 511 may be different, and for example, the groove depth and groove width of the three first grooves 511 may be different.

In some exemplary embodiments, as shown in FIGS. 25 to 28, the three second grooves 531 may correspond one-to-one with the three first positions 524, and the three first grooves 511 may also correspond one-to-one with the three first positions 524, forming the three second grooves 531 and the three first grooves 511 that also correspond one-to-one. The orthographic projection of the second groove 531 on the base substrate and the orthographic projection of the first groove 511 on the base substrate also overlap in a one-to-one correspondence, and the orthographic projections of the first electrode plate 51 and the second electrode plate 52 on the base substrate 10 do not overlap with the orthographic projection of the second input terminal 536 on the base substrate 10.

In some exemplary embodiments, as shown in FIGS. 25 to 28, when laser is used for maintenance, the second signal line connected to a problematic capacitor is cut, possibly to a position near the second position 535 of the storage capacitor, continuing to cut downward in a direction perpendicular to the base substrate 10, and to the base substrate 10. In particular, the cutting position of the laser corresponds to the notch 70, so that only the second signal line and a small part of the third electrode plate 53 are cut off, and the second electrode plate 52 and the first electrode plate 51 are not cut. Even if the part of the third electrode plate 53 that has been cut is melted, it will not come into contact with the second electrode plate 52, so that the short circuit can be avoided, normal use can be achieved, and the success rate of maintenance can be improved.

FIG. 29 is a schematic diagram of another storage capacitor according to an exemplary embodiment of the present disclosure. In some exemplary embodiments, as shown in FIG. 29, the first electrode plate 51 and the second electrode plate 52 may both be provided with a notch 70, the third electrode plate 53 is not provided with a groove structure, but has one second input terminal 536, and the second electrode plate 52 has a first input terminal 525. In a direction perpendicular to the base substrate, the notch 70 corresponds to the second input terminal 536 on the third electrode plate 53, such that both the first electrode plate 51 and the second electrode plate 52 are staggered from the second input terminal 536, and the first input terminal 525 and the second input terminal 536 are also arranged in a staggered manner, but it is not limited thereto. For example, the third electrode plate 53 may have a plurality of second input terminals 536, and the first electrode plate 51 and the second electrode plate 52 may both be provided with a plurality of notches 70. The notches 70 of the first electrode plate 51 may correspond one-to-one with the second input terminals 536, and the notches 70 of the second electrode plate 52 may correspond one-to-one with the second input terminals 536.

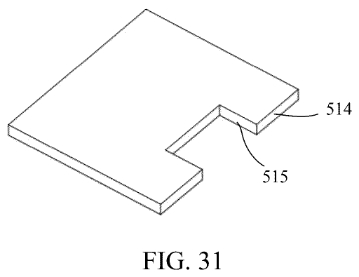

FIG. 30 is a schematic diagram of a second electrode plate in FIG. 29, and FIG. 31 is a schematic diagram of a first electrode plate in FIG. 29. In some exemplary embodiments, as shown in FIGS. 29 to 31, the circumferential edge of the first electrode plate 51 may include one third edge 514, and the third edge 514 is provided with a third groove 515 recessed inward. The third groove 515 penetrates the first electrode plate 51, the third groove 515 may be a rectangular groove, and the third groove 515 constitutes one notch 70. A groove width of the third groove 515 may be 15 μm to 30 μm, and a groove depth of the third groove 515 may be 7 μm to 15 μm. The circumferential edge of the second electrode plate 52 may include a fourth edge 526, the fourth edge 526 may be provided with a fourth groove 527 recessed inward, the fourth groove 527 penetrates the second electrode plate 52, the fourth groove 527 may be a rectangular groove, and the fourth groove 527 constitutes another notch 70. The groove shape, the groove width, and the groove depth of the third groove 515 and the fourth groove 527 are consistent, so that an orthographic projection of the third groove 515 on the base substrate and an orthographic projection of the fourth groove 527 on the base substrate overlap, but it is not limited thereto. For example, at least one of the groove shape, the groove width, and the groove depth of the third groove 515 and the fourth groove 527 are inconsistent, so that the orthographic projection of the third groove 515 on the base substrate and the orthographic projection of the fourth groove 527 on the base substrate partially overlap rather than completely overlap.

In some exemplary embodiments, as shown in FIG. 29, in preparing the display substrate of the present example, the first conductive layer 22, the buffer layer 25, the active layer (not shown in the figure), the gate insulating layer (not shown in the figure), the second conductive layer 23, the first insulating layer 26, and the third conductive layer 24 may be sequentially prepared on the base substrate to form the storage capacitor of the present example. The mask used in preparing the first conductive layer 22 needs to be designed according to the first electrode plate 51 having the third groove 515, and the mask used in preparing the second conductive layer 23 needs to be designed according to the second electrode plate 52 having the fourth groove 527. When the buffer layer 25 is prepared, the buffer layer 25 is formed at least between the first electrode plate 51 and the second electrode plate 52, and is also formed in the third groove 515 of the first electrode plate 51. When the first insulating layer 26 is prepared, the first insulating layer 26 is formed at least on a surface of the second electrode plate 52 close to the third electrode plate 53, and is also formed in the fourth groove 527 of the second electrode plate 52.

### (6) Preparing a Passivation Layer.

In some exemplary embodiments, preparing the passivation layer includes depositing a passivation layer film on the third conductive layer to form a passivation layer which covers the third conductive layer and the first insulating layer. The passivation layer film can be deposited by chemical vapor deposition technology. After the passivation layer is formed, the drive circuit layer of the display substrate is substantially completed.

### (7) Preparing a Light-Emitting Structure Layer and an Encapsulation Structure Layer.

In some exemplary embodiments, preparing the light-emitting structure layer and the encapsulation structure layer includes on the above-obtained drive circuit layer, sequentially evaporating to obtain the light-emitting structure layer and depositing to obtain the encapsulation structure layer, to complete the preparation of the display substrate.

In combination with the above embodiments, the display substrate of the present disclosure is provided with a notch, so that on the basis that the storage capacitor does not affect the charge storage capability of the capacitor, even if the laser cuts to the first input terminal or the second output terminal during maintenance, the two electrode plates will not be melted and short-circuited. This improves the maintenance success rate, reduces screen scrapping caused by poor capacitance, and improves product yield and quality.

The present disclosure also provides a manufacturing method of a display substrate. The display substrate includes a display area and a bezel area located on at least one side of the display area. The bezel area includes at least a gate driving circuit including at least a storage capacitor, a first signal line, and a second signal line. The storage capacitor includes a first electrode plate, a second electrode plate, and a third electrode plate that are stacked.

The manufacturing method includes: forming a first conductive layer on a base substrate, the first electrode plate being disposed in the first conductive layer; forming a second conductive layer on a side of the first conductive layer away from the base substrate, the first signal line and the second electrode plate being disposed in the second conductive layer, the second electrode plate having a first input terminal connected to the first signal line; and forming a third conductive layer on a side of the second conductive layer away from the base substrate, the second signal line and the third electrode plate being disposed in the third conductive layer, the third electrode plate having a second input terminal connected to the second signal line.

Two of the first electrode plate, the second electrode plate, and the third electrode plate are provided with notches, and orthographic projections of the notches on the base substrate are disposed to overlap with an orthographic projection of the first input terminal on the base substrate, or an orthographic projection of the second input terminal on the base substrate.

In some exemplary embodiments, a display device is provided, which includes the display substrate described above. The display device may be any product or component with a display function, such as a mobile phone, a tablet computer, a television, a display, a laptop computer, a digital photo frame, and a navigator, which is not limited in the embodiments of the present invention.

The above described embodiments are only illustrative of several embodiments of the present disclosure, and the description thereof is more specific and detailed, but the contents described are only embodiments adopted for the convenience of understanding the present disclosure, and are not intended to limit the present disclosure. Any person skilled in the art to which the present disclosure pertains may make any modification and variation in implementation forms and details without departing from the spirit and scope disclosed in the present disclosure. However, the scope of patent protection of the present disclosure is still subject to the scope defined by the appended claims.

1. A display substrate comprising a display area and a bezel area located on at least one side of the display area, the bezel area comprising at least a gate driving circuit, the gate driving circuit comprising at least a storage capacitor, a first signal line, and a second signal line, the storage capacitor comprising a first electrode plate, a second electrode plate, and a third electrode plate that are stacked;
wherein in a direction perpendicular to the display substrate, the display substrate comprises a first conductive layer, a second conductive layer, and a third conductive layer sequentially disposed on a base substrate along a direction away from the base substrate;
the first electrode plate is disposed in the first conductive layer;
the first signal line and the second electrode plate are disposed in the second conductive layer, the second electrode plate having a first input terminal connected to the first signal line;
the second signal line and the third electrode plate are disposed in the third conductive layer, the third electrode plate having a second input terminal connected to the second signal line; and
two of the first electrode plate, the second electrode plate, and the third electrode plate are provided with notches, and orthographic projections of the notches on the base substrate are configured to overlap with an orthographic projection of the first input terminal on the base substrate, or an orthographic projection of the second input terminal on the base substrate.

2. The display substrate according to claim 1, wherein both the first electrode plate and the third electrode plate are provided with the notches, and the orthographic projections of the notches on the base substrate overlap with the orthographic projection of the first input terminal on the base substrate; or
both the first electrode plate and the second electrode plate are provided with the notches, and the orthographic projections of the notches on the base substrate overlap with the orthographic projection of the second input terminal on the base substrate.

3. The display substrate according to claim 2, wherein a circumferential edge of the first electrode plate is provided with a first groove recessed inward, the first groove extending in a direction perpendicular to the base substrate and penetrating the first electrode plate;
a circumferential edge of the third electrode plate is provided with a second groove recessed inward, the second groove extending in the direction perpendicular to the base substrate and penetrating the third electrode plate; and
both the first groove and the second groove constitute the notches.

4. The display substrate according to claim 3, wherein the circumferential edge of the first electrode plate comprises at least a first edge, the first edge being located on a side of the first electrode plate close to the first input terminal, the first groove being provided on the first edge;
the circumferential edge of the third electrode plate comprises at least a second edge, the second edge being located on a side of the third electrode plate close to the first input terminal, the second groove being provided on the second edge; and
the first edge and the second edge are flush in the direction perpendicular to the base substrate, and an orthographic projection of the first groove on the base substrate and an orthographic projection of the second groove on the base substrate at least partially overlap.

5. The display substrate according to claim 4, wherein the orthographic projection of the first groove on the base substrate is within a range of the orthographic projection of the second groove on the base substrate; or the orthographic projection of the second groove on the base substrate is within a range of the orthographic projection of the first groove on the base substrate; or the orthographic projection of the first groove on the base substrate and the orthographic projection of the second groove on the base substrate overlap.

6. The display substrate according to claim 5, wherein both a shape of the first groove and a shape of the second groove are rectangular or arc-shaped in a direction parallel to the base substrate.

7. The display substrate according to claim 5, wherein a groove width of the first groove and a groove width of the second groove are both 15 μm to 30 μm, and a groove depth of the first groove and a groove depth of the second groove are both 7 μm to 15 μm.

8. The display substrate according to claim 2, wherein a circumferential edge of the first electrode plate is provided with a third groove recessed inward, the third groove extending in a direction perpendicular to the base substrate and penetrating the first electrode plate;
a circumferential edge of the second electrode plate is provided with a fourth groove recessed inward, the fourth groove extending in the direction perpendicular to the base substrate and penetrating the second electrode plate; and
both the third groove and the fourth groove constitute the notches, and an orthographic projection of the third groove on the base substrate and an orthographic projection of the fourth groove on the base substrate at least partially overlap.

9. The display substrate according to claim 8, wherein the orthographic projection of the third groove on the base substrate and the orthographic projection of the fourth groove on the base substrate overlap, a groove width of the third groove is 15 μm to 30 μm, and a groove depth of the third groove is 7 μm to 15 μm.

10. The display substrate according to claim 1, wherein an orthographic projection of the first electrode plate on the base substrate and an orthographic projection of the third electrode plate on the base substrate are configured to at least partially overlap; and
the first electrode plate and the third electrode plate are electrically connected through a metal hole structure, and the second electrode plate is provided with a first opening for avoiding the metal hole structure.

11. The display substrate according to claim 2, wherein the second electrode plate is provided with a plurality of first input terminals, and the third electrode plate is provided with a plurality of second input terminals; and
a plurality of notches on the first electrode plate and a plurality of notches on the third electrode plate are provided and correspond one-to-one with the first input terminals; or a plurality of notches on the first electrode plate and a plurality of notches on the second in electrode plate are provided and correspond one-to-one with the second input terminals.

12. The display substrate according to claim 1, wherein the display substrate further comprises a buffer layer and a first insulating layer, the buffer layer is configured to cover a surface of the first conductive layer away from the base substrate, and the first insulating layer is configured to cover a surface of the second conductive layer away from the base substrate.

13. A display device, comprising the display substrate according to claim 1.

14. A manufacturing method of a display substrate, wherein the display substrate comprises a display area and a bezel area located on at least one side of the display area, the bezel area comprises at least a gate driving circuit, the gate driving circuit at least comprises at least a storage capacitor, a first signal line, and a second signal line, and the storage capacitor comprises a first electrode plate, a second electrode plate, and a third electrode plate that are stacked;
the manufacturing method comprises:
forming a first conductive layer on a base substrate, the first electrode plate being disposed in the first conductive layer;
forming a second conductive layer on a side of the first conductive layer away from the base substrate, the first signal line and the second electrode plate being disposed in the second conductive layer, the second electrode plate having a first input terminal connected to the first signal line; and
forming a third conductive layer on a side of the second conductive layer away from the base substrate, the second signal line and the third electrode plate being disposed in the third conductive layer, the third electrode plate having a second input terminal connected to the second signal line; and
two of the first electrode plate, the second electrode plate, and the third electrode plate are provided with notches, and orthographic projections of the notches on the base substrate are configured to overlap with an orthographic projection of the first input terminal on the base substrate, or an orthographic projection of the second input terminal on the base substrate.

15. The display substrate according to claim 2, wherein an orthographic projection of the first electrode plate on the base substrate and an orthographic projection of the third electrode plate on the base substrate are configured to at least partially overlap; and
the first electrode plate and the third electrode plate are electrically connected through a metal hole structure, and the second electrode plate is provided with a first opening for avoiding the metal hole structure.

16. The display substrate according to claim 3, wherein an orthographic projection of the first electrode plate on the base substrate and an orthographic projection of the third electrode plate on the base substrate are configured to at least partially overlap; and
the first electrode plate and the third electrode plate are electrically connected through a metal hole structure, and the second electrode plate is provided with a first opening for avoiding the metal hole structure.

17. The display substrate according to claim 3, wherein the second electrode plate is provided with a plurality of first input terminals, and the third electrode plate is provided with a plurality of second input terminals; and
a plurality of notches on the first electrode plate and a plurality of notches on the third electrode plate are provided and correspond one-to-one with the first input terminals; or a plurality of notches on the first electrode plate and a plurality of notches on the second electrode plate are provided and correspond one-to-one with the second input terminals.

18. The display substrate according to claim 4, wherein the second electrode plate is provided with a plurality of first input terminals, and the third electrode plate is provided with a plurality of second input terminals; and
a plurality of notches on the first electrode plate and a plurality of notches on the third electrode plate are provided and correspond one-to-one with the first input terminals; or a plurality of notches on the first electrode plate and a plurality of notches on the second electrode plate are provided and correspond one-to-one with the second input terminals.

19. The display substrate according to claim 2, wherein the display substrate further comprises a buffer layer and a first insulating layer, the buffer layer is configured to cover a surface of the first conductive layer away from the base substrate, and the first insulating layer is configured to cover a surface of the second conductive layer away from the base substrate.

20. The display substrate according to claim 3, wherein the display substrate further comprises a buffer layer and a first insulating layer, the buffer layer is configured to cover a surface of the first conductive layer away from the base substrate, and the first insulating layer is configured to cover a surface of the second conductive layer away from the base substrate.
